(19) United States
(12) Patent Application Publication
(10) Pub. No.: US 2026/0212912 A1
(43) Pub. Date: Jul. 23, 2026

(54) MEMORY DEVICE AND MEMORY SYSTEM INCLUDING THE SAME

(71) Applicant: Samsung Electronics Co., Ltd., Suwon-si (KR)

(72) Inventors: Soyeong Shin, Suwon-si (KR); Daehyun Kwon, Suwon-si (KR); Seungjun Bae, Suwon-si (KR)

(21) Appl. No.: 19/287,014

(22) Filed: Jul. 31, 2025

(30) Foreign Application Priority Data
Jan. 21, 2025 (KR) 10-2025-0008898

(51) Int. Cl. G11C 11/4091; G11C 11/4076; G11C 11/4093

(52) U.S. Cl. CPC G11C 11/4091; G11C 11/4076; G11C 11/4093

(57) ABSTRACT

A memory device includes a buffer configured to compare a data signal to a reference voltage and generate an amplified signal, a summation circuit configured to generate a summation output signal based on the amplified signal, and a sampler including a sampling circuit configured to generate a sampling signal by sampling the summation output signal based on a clock signal, and a first equalization circuit coupled to the sampling circuit and configured to equalize the sampling signal based on a feedback sampling signal sampled prior to the sampling signal. The first equalization circuit includes (i) a first transistor circuit configured to receive the feedback sampling signal and (ii) a second transistor circuit between the first transistor circuit and the sampling circuit and configured to receive a bias voltage associated with an equalization coefficient.

### CROSS-REFERENCE TO RELATED APPLICATION

This application claims priority to Korean Patent Application No. 10-2025-0008898, filed in the Korean Intellectual Property Office on January 21, 2025, the entire contents of which are hereby incorporated by reference.

### BACKGROUND

A semiconductor memory device may be classified into a volatile memory device and a nonvolatile memory device depending on whether data stored therein is lost when a power supply is interrupted. A volatile memory device may lose stored data when the power supply is cut off, and a nonvolatile memory device may preserve stored data even if the power supply is interrupted.

### SUMMARY

As the performance of semiconductor memory devices has improved, there has been an increasing demand for high communication speed (or interface speed) between a memory controller and a semiconductor memory. The increased communication speed may affect the performance of a receiver included in the semiconductor memory device. For example, due to various factors such as a skin effect or dielectric loss, a data signal transmitted through a channel may include noise such as inter-symbol interference (ISI), and consequently, the quality of the data signal transmitted at high speed may degrade.

The present disclosure relates to a memory device and a memory system including the same, which address the above issues.

The problems intended to be solved by the present disclosure are not limited to those described above, and other problems not mentioned will be clearly understood by those of ordinary skill in the art from the following description of the disclosure.

In general, in some aspects, the present disclosure provides a memory device including a buffer configured to compare a data signal to a reference voltage and generate an amplified signal, a summation circuit configured to generate a summation output signal based on the amplified signal, and a sampler including a sampling circuit configured to generate a sampling signal by sampling the summation output signal based on a clock signal, and a first equalization circuit coupled to the sampling circuit and configured to equalize the sampling signal based on a feedback sampling signal sampled prior to the sampling signal. The first equalization circuit may include a first transistor into which the feedback sampling signal is input, and a second transistor disposed between the first transistor and the sampling circuit, into which a bias voltage associated with an equalization coefficient is input.

In general, in some aspects, the present disclosure provides a memory device including a receiver circuit configured to process a data signal received from a memory controller and generate output data, and a control logic circuit configured to control the receiver circuit. The receiver circuit may include a buffer configured to compare the data signal to a reference voltage and generate an amplified signal, a summation circuit configured to generate a summation output signal based on the amplified signal, and a sampler including a sampling circuit configured to generate a sampling signal by sampling the summation output signal based on a clock signal, and an equalization circuit coupled to the sampling circuit and configured to equalize the sampling signal based on a feedback sampling signal sampled prior to the sampling signal. The equalization circuit may include a first transistor into which the feedback sampling signal is input, and a second transistor disposed between the first transistor and the sampling circuit, into which a bias voltage associated with an equalization coefficient is input.

In general, in some aspects, the present disclosure provides a memory system including a memory device and a memory controller configured to write data into the memory device or read out data stored in the memory device. The memory device may include a receiver circuit configured to process a data signal received from the memory controller and generate output data, and a control logic circuit configured to control the receiver circuit. The receiver circuit may include a buffer configured to compare the data signal to a reference voltage and generate an amplified signal, a summation circuit configured to generate a summation output signal based on the amplified signal, and a sampler including a sampling circuit configured to generate a sampling signal by sampling the summation output signal based on a clock signal, and an equalization circuit coupled to the sampling circuit and configured to equalize the sampling signal based on a feedback sampling signal sampled prior to the sampling signal. The equalization circuit may include a first transistor into which the feedback sampling signal is input, and a second transistor disposed between the first transistor and the sampling circuit, into which a bias voltage associated with an equalization coefficient is input.

In some implementations, because the equalization circuit is integrated as a constituent element of the sampler, the output signal of the sampler generated in the previous phase domain may be directly provided to the equalization circuit of the next phase domain, thereby shortening the feedback path and keeping the feedback time within one unit interval (UI).

In some implementations, the current flow path of the feedback signal may be set more concisely. Through such a configuration, signal delay in the feedback path decreases, and feedback time may be effectively reduced.

In some implementations, the equalization coefficient applied to the equalization circuit may be stably maintained without being affected by variations in the supply voltage.

In some implementations, a simplified reset effect may be implemented with a single PMOS transistor without the need to implement a separate logic circuit.

The effects obtainable through the present disclosure are not limited to those described above. Additional technical effects not mentioned will be clearly understood by those of ordinary skill in the art from the following detailed description.

### BRIEF DESCRIPTION OF THE DRAWINGS

FIG. 1 is a block diagram for describing an example of a transmitter-receiver system.

FIG. 2 is a diagram illustrating an example of an effect of inter-symbol interference.

FIG. 3 is a diagram illustrating an example of a receiver circuit.

FIG. 4 is a diagram illustrating an example of a summation circuit.

FIG. 5 is a diagram illustrating an example of a sampler.

FIG. 6 is a diagram illustrating an example of a bias voltage generation circuit.

FIG. 7 is a diagram illustrating an example of a sampler.

FIG. 8 is a diagram illustrating an example of an operation of a sampler.

FIG. 9 is a block diagram illustrating an example of a memory system.

FIG. 10 is a block diagram illustrating an example of an electronic device having a receiver circuit.

### DETAILED DESCRIPTION

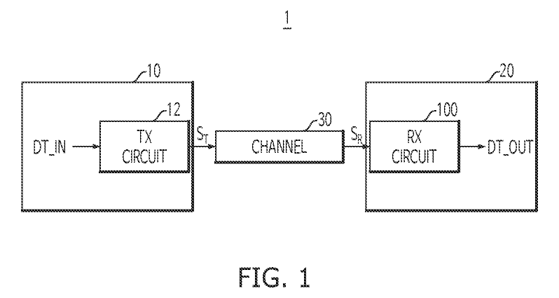

Hereinafter, various implementations of the present disclosure will be described with reference to FIGS. 1-10. Throughout the specification, identical reference numerals may refer to identical constituent elements.

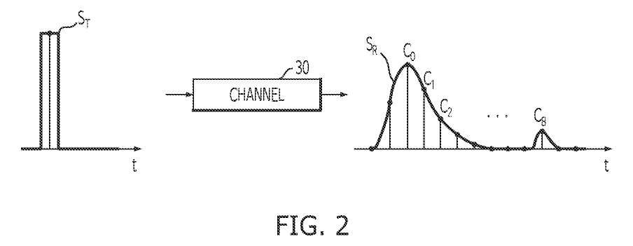

FIG. 1 is a block diagram for describing a transmitter-receiver system according to some implementations of the present disclosure. FIG. 2 is a diagram for describing the effect of inter-symbol interference.

Referring to FIG. 1, a transmitter-receiver system 1 according to some implementations of the present disclosure may include a transmitter 10 and a receiver 20 configured to communicate with each other through a channel 30.

The transmitter 10 may include a transmitting circuit 12. The transmitting circuit 12 may receive transmission data DT_IN that is to be delivered, and may output a transmission signal ST based on the transmission data DT_IN. The transmitting circuit 12 may deliver the transmission signal ST to the receiver 20 through the channel 30. As the transmission signal ST passes through the channel 30 to the receiver 20, it may be changed into a reception signal SR. In some implementations, the transmitting circuit 12 may perform a signal equalization operation to compensate for channel loss.

The receiver 20 may include a receiver circuit 100. The receiver circuit 100 may receive the reception signal SR through the channel 30 and may output reception data DT_OUT based on the reception signal SR. In some examples, the transmission signal ST may be distorted when passing through the channel 30 due to response characteristics or noise (for example, interference) of the channel 30. Accordingly, the receiver circuit 100 may receive the reception signal SR that has been distorted by the response characteristics or noise of the channel 30. In other words, the reception signal SR may be a signal that reflects the response characteristics or noise of the channel 30 onto the transmission signal ST.

In some examples, if the transmitter 10 ideally operates to normally remove inter-symbol interference (ISI), and if there is no noise in the channel 30, the originally transmitted data DT_IN may be correctly determined via the reception signal SR. However, due to various external factors, the transmitter 10 may not operate ideally, and noise may enter the channel 30, so the original transmission data DT_IN may not be correctly determined based on the reception signal SR.

Specifically, referring to FIG. 2, in some implementations, the transmission signal ST transmitted by the transmitter 10 may be a single square pulse. A reception signal SR, which is received through a non-ideal channel (for example, a channel with loss), may have a shape different from the transmission signal ST. For example, when the analog signal of the reception signal SR is sampled at the receiver 20, it may have a value C0, and due to the defective characteristics of the non-ideal channel, the effect of the transmitted pulse may persist for multiple unit intervals, forming residual signals (C1, C2, etc.) called residuals. In a high-speed serial link, a series of pulses may be transmitted at a rate called the aggregate data rate, and each pulse may represent a logical high (binary 1) or a logical low (binary 0). Residual signals from previously received pulses may cause inter-symbol interference when the current pulse is received, because the residual signals overlap the current pulse being received.

According to some implementations of the present disclosure, the receiver circuit 100 may include an equalization circuit configured to equalize the reception signal SR. In some implementations, the equalization circuit may include a decision feedback equalizer. A decision feedback equalizer may be used after a decision is made as to whether the transmitted pulse ST was 0 or 1. Once the decision is made, the residuals of the analog signal corresponding to the transmitted pulse ST are calculated in accordance with the determined value, and the calculated residuals are subtracted from a subsequently received signal. As a result, the equalized signal may have a reduced effect of inter-symbol interference.

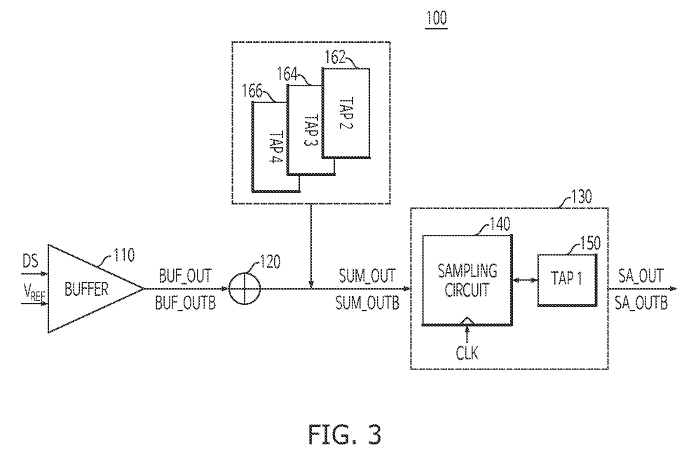

FIG. 3 is a diagram for describing a receiver circuit according to some implementations of the present disclosure.

Referring to FIG. 3, the receiver circuit 100 may include a buffer 110, a summation circuit 120, and a sampler 130.

The buffer 110 may receive a data signal DS and a reference voltage VREF and process an input signal. The buffer 110 may generate a differential signal based on the voltage difference between the data signal DS and the reference voltage VREF. In addition, the buffer 110 may amplify the generated differential signal so as to generate amplified signals BUF_OUT and BUF_OUTB. For example, the amplified signal BUF_OUT may have the same phase as the data signal DS, and the amplified signal BUF_OUTB may have a phase opposite to that of the data signal DS. The generated amplified signals BUF_OUT and BUF_OUTB may be provided to the summation circuit 120.

In the following description, references to a particular signal may be understood to encompass differential signals. For example, the term “amplified signal (BUF_OUT, BUF_OUTB)” may collectively refer to both the amplified signal BUF_OUT and the differential amplified signal BUF_OUTB whose phase is opposite that of BUF_OUT. In addition, when it is stated that a certain signal has a first logic level (for example, high), it may be understood that its differential signal has a second logic level (for example, low). For example, if BUF_OUT is at a first logic level, it may be understood that BUF_OUTB, the differential signal of BUF_OUT, is simultaneously at a second logic level. This may apply to both digital and analog signals.

The summation circuit 120 may receive the amplified signals BUF_OUT and BUF_OUTB from the buffer 110. The summation circuit 120 may generate summation output signals SUM_OUT and SUM_OUTB based on the amplified signals BUF_OUT and BUF_OUTB. In some examples, the summation circuit 120 may perform a continuous-time linear equalization (CTLE) process based on the amplified signals BUF_OUT and BUF_OUTB, thereby generating the summation output signals SUM_OUT and SUM_OUTB.

Furthermore, the summation output signals SUM_OUT and SUM_OUTB may be signals to which an equalization coefficient is applied by at least one of multiple equalization circuits, for example, a second equalization circuit 162, a third equalization circuit 164, or a fourth equalization circuit 166, output from the summation circuit 120. The second equalization circuit 162, the third equalization circuit 164, and the fourth equalization circuit 166 may each have various equalization coefficient values set so as to effectively remove inter-symbol interference that may occur in the input signal. In some implementations, the second equalization circuit 162, the third equalization circuit 164, and the fourth equalization circuit 166 may be referred to as a second tap, a third tap, and a fourth tap, respectively.

The sampler 130 may receive the summation output signals SUM_OUT and SUM_OUTB from the summation circuit 120. The sampler 130 may generate sampling signals SA_OUT and SA_OUTB based on the summation output signals SUM_OUT and SUM_OUTB. The sampling signals SA_OUT and SA_OUTB may be signals output from a sampling circuit 140, to which an equalization coefficient has been applied by a first equalization circuit 150. To this end, the sampler 130 may include the sampling circuit 140, which is configured to generate the sampling signals by sampling the summation output signals SUM_OUT and SUM_OUTB based on a clock signal CLK, and the first equalization circuit 150, which is coupled to the sampling circuit 140 and configured to equalize the currently sampled signal based on a feedback sampling signal (or previous sampling signal) that was sampled prior to the currently sampled signal. Here, the feedback sampling signal may be a signal sampled one unit interval (UI) prior to the currently sampled signal. In some implementations, the first equalization circuit 150 may feed back the feedback sampling signal sampled prior to the currently sampled signal and, based thereon, may equalize the currently sampled signal.

The sampling circuit 140 may sample the summation output signals SUM_OUT and SUM_OUTB in synchronization with a rising or falling edge of the clock signal CLK and may deliver the generated sampling signals to the first equalization circuit 150. In some implementations, the sampling circuit 140 may be designed to perform stable signal sampling in a high-speed data transmission environment and may correct timing changes of the input signal in real time to maintain the accuracy of a sampling frequency. Also, the sampling circuit 140 may be configured to suppress sampling errors due to jitter in the clock signal CLK. In some examples, the sampling circuit 140 may deliver the sampling signal currently being sampled to the first equalization circuit 150 so that the first equalization circuit 150 can equalize a subsequently generated sampling signal based on the currently sampled signal.

The first equalization circuit 150 may be configured to correct the current sampling signal based on a previously sampled signal. The first equalization circuit 150 may apply an equalization coefficient to remove or reduce inter-symbol interference in the input signal so as to correct signal distortion and improve the quality of the sampling signals SA_OUT and SA_OUTB. In addition, the first equalization circuit 150 may consider both amplitude and phase characteristics of the signal so as to minimize signal distortion that may occur during data transmission.

In some examples, each of the first equalization circuit 150, the second equalization circuit 162, the third equalization circuit 164, and the fourth equalization circuit 166 may be implemented as a decision feedback equalizer (DFE). Each of the first equalization circuit 150, the second equalization circuit 162, the third equalization circuit 164, and the fourth equalization circuit 166 may receive the previously sampled signal as feedback and perform an equalization operation to address issues caused by inter-symbol interference based on the feedback. Here, the first equalization circuit 150 may receive data that is 1 UI prior in time as feedback, the second equalization circuit 162 may receive data that is 2 UI prior, the third equalization circuit 164 may receive data that is 3 UI prior, and the fourth equalization circuit 166 may receive data that is 4 UI prior.

Although not illustrated, the summation circuit 120 may include a first summation circuit and a second summation circuit. The first summation circuit may generate a first summation circuit output signal based on the amplified signals BUF_OUT and BUF_OUTB. The second summation circuit may generate a second summation circuit output signal based on the amplified signals BUF_OUT and BUF_OUTB. The first summation circuit output signal may be provided to a first sampling circuit and a third sampling circuit (to be described), and the second summation circuit output signal may be provided to a second sampling circuit and a fourth sampling circuit (to be described).

The sampling circuit 140 may include first, second, third, and fourth sampling circuits. The first to fourth sampling circuits may each receive a clock signal having a 90-degree phase difference from one another and may generate a sampling signal in synchronization with the corresponding clock signal. For example, the first sampling circuit may generate a first sampling signal in accordance with a first clock signal, the second sampling circuit may generate a second sampling signal in accordance with a second clock signal, the third sampling circuit may generate a third sampling signal in accordance with a third clock signal, and the fourth sampling circuit may generate a fourth sampling signal in accordance with a fourth clock signal.

The first clock signal, the second clock signal, the third clock signal, and the fourth clock signal are clock signals having 90-degree phase differences, so they may have the same frequency but cause signals to occur at different time points. For example, if the first clock signal is a reference clock signal, the second clock signal may have a phase delayed by 90 degrees relative to the first clock signal. In addition, the third clock signal may have a 180-degree phase difference from the first clock signal and be delayed by 90 degrees relative to the second clock signal. Likewise, the fourth clock signal may have a 180-degree phase difference from the second clock signal and be delayed by 90 degrees relative to the third clock signal.

In addition, the first equalization circuit 150 may include 1_1, 1_2, 1_3, and 1_4 equalization circuits. The 1_1 equalization circuit may be coupled to the first sampling circuit and configured to equalize the first sampling signal, the 1_2 equalization circuit may be coupled to the second sampling circuit and configured to equalize the second sampling signal, the 1_3 equalization circuit may be coupled to the third sampling circuit and configured to equalize the third sampling signal, and the 1_4 equalization circuit may be coupled to the fourth sampling circuit and configured to equalize the fourth sampling signal.

For example, the first sampling signal generated by the first sampling circuit may be directly input to the 1_2 equalization circuit, and the 1_2 equalization circuit may equalize the second sampling signal based on the first sampling signal that was sampled prior to the sampling time of the second sampling signal. Similarly, the second sampling signal generated by the second sampling circuit may be directly input to the 1_3 equalization circuit, and the 1_3 equalization circuit may equalize the third sampling signal based on the second sampling signal that was sampled prior to the sampling time of the third sampling signal.

In this manner, each of the 1_1 to 1_4 equalization circuits may be configured to receive as feedback a sampling signal generated 1 UI before the sampling time of each sampling signal, and perform equalization based thereon. Consequently, the information necessary to equalize the currently sampled signal may be provided in time to correct signal distortion. Thus, keeping the feedback time for the first equalization circuit within 1 UI may be an important factor for ensuring the performance and stability of the equalization process.

According to various implementations of the present disclosure, by integrating the first equalization circuit 150 within the sampler 130, the time required for a previous sampling signal to be fed back may be shortened, and the feedback time for the first equalization circuit 150 may remain within 1 UI. Specifically, by integrating the first equalization circuit 150 into the sampler 130, the output signal of the sampler 130 may be directly fed back to the first equalization circuit 150 of the next phase domain. Accordingly, because the output signal of the sampler 130 generated in the previous phase domain is directly delivered to the first equalization circuit 150 of the next phase domain, the feedback path is shortened, and the feedback time may be kept within 1 UI.

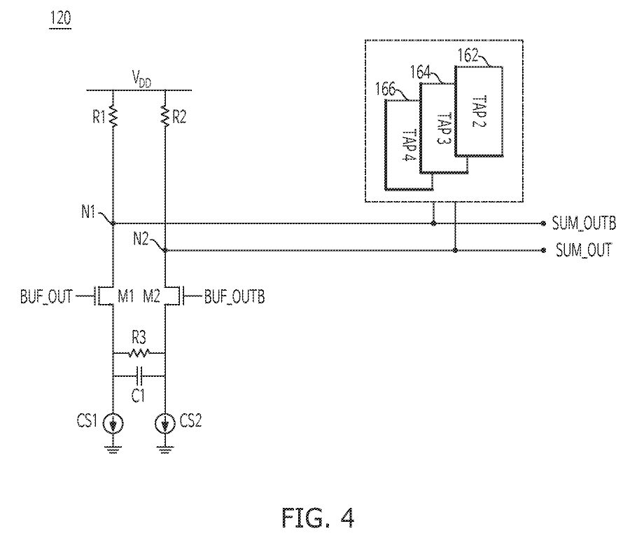

FIG. 4 is a diagram for describing a summation circuit according to some implementations of the present disclosure.

Referring to FIG. 4, the summation circuit 120 may include first to third resistors R1, R2, R3, first to second transistors M1 and M2, a first capacitor C1, and first to second current sources CS1 and CS2.

The summation circuit 120 may receive the amplified signals BUF_OUT and BUF_OUTB and may output the summation output signals SUM_OUT and SUM_OUTB. The amplified signals BUF_OUT and BUF_OUTB may be signals output from the buffer 110 of FIG. 3. The summation output signals SUM_OUT and SUM_OUTB may be signals whose waveforms are adjusted from the amplified signals BUF_OUT and BUF_OUTB or signals having an amplified magnitude of BUF_OUT and BUF_OUTB. In some implementations, both the amplified signals BUF_OUT and BUF_OUTB and the summation output signals SUM_OUT and SUM_OUTB may be configured as differential signals.

The first transistor M1 may receive the amplified signal BUF_OUT through its gate terminal. The drain terminal of the first transistor M1 may be connected to a first node together with one end of the first resistor R1. The other end of the first resistor R1 may be connected to a supply voltage VDD. The source terminal of the first transistor M1 may be connected to the first current source CS1, one end of the third resistor R3, and one end of the first capacitor C1. The first transistor M1 may control the amount of current flowing between its drain terminal and its source terminal according to the amplified signal BUF_OUT or may operate as a switch. In some implementations, the first transistor M1 may be implemented as an NMOS transistor, but it is not limited thereto.

The second transistor M2 may receive the amplified signal BUF_OUTB through its gate terminal. The drain terminal of the second transistor M2 may be connected to a second node N2 together with one end of the second resistor R2. The other end of the second resistor R2 may be connected to the supply voltage VDD. The source terminal of the second transistor M2 may be connected to the second current source CS2, the other end of the third resistor R3, and the other end of the first capacitor C1. The second transistor M2 may control the amount of current flowing between its drain terminal and its source terminal according to the amplified signal BUF_OUTB or may operate as a switch. In some implementations, the second transistor M2 may be implemented as an NMOS transistor, but it is not limited thereto.

The first current source CS1 may generate a bias current flowing through the first transistor M1. The second current source CS2 may generate a bias current flowing through the second transistor M2. In some implementations, each of the current sources CS1 and CS2 may be a transistor that receives a bias voltage through its gate terminal, is connected to M1 or M2 at its drain terminal, and is connected to a ground voltage at its source terminal.

The third resistor R3 and the first capacitor C1 may be connected in parallel between the source terminals of the transistors M1 and M2. The third resistor R3 and the first capacitor C1 may amplify, compensate, or restore high-frequency components of a transmission signal that are weakened due to channel loss. Based on these characteristics, the summation circuit 120 may be implemented as a continuous-time linear equalizer (CTLE).

In some examples, the summation circuit 120 may receive the amplified signals BUF_OUT and BUF_OUTB so as to generate the summation output signals SUM_OUT and SUM_OUTB. In some implementations, the summation circuit 120 may compare the voltage difference of an input differential signal and may amplify it to generate an output signal. From this viewpoint, the summation circuit 120 may be implemented as a variable gain amplifier (VGA).

In some implementations, at least one of the second equalization circuit 162, the third equalization circuit 164, or the fourth equalization circuit 166 may be connected to each line of the summation output signals SUM_OUT and SUM_OUTB. Based on a feedback signal from the sampler 130 of FIG. 3, at least one of the second equalization circuit 162, the third equalization circuit 164, or the fourth equalization circuit 166 may equalize the summation output signals SUM_OUT and SUM_OUTB.

In some implementations, in the receiver circuit illustrated in FIG. 3, if the currently sampled signal is called the “current sampling signal,” and if the sampling signal input to the first equalization circuit 150 is called the “previous sampling signal,” then the sampling signal input to the second equalization circuit 162 may be a signal sampled even earlier than the previous sampling signal. For example, the previous sampling signal may be sampled 1 UI earlier than the current sampling signal, and the sampling signal input to the second equalization circuit 162 may be sampled 1 UI earlier than the previous sampling signal.

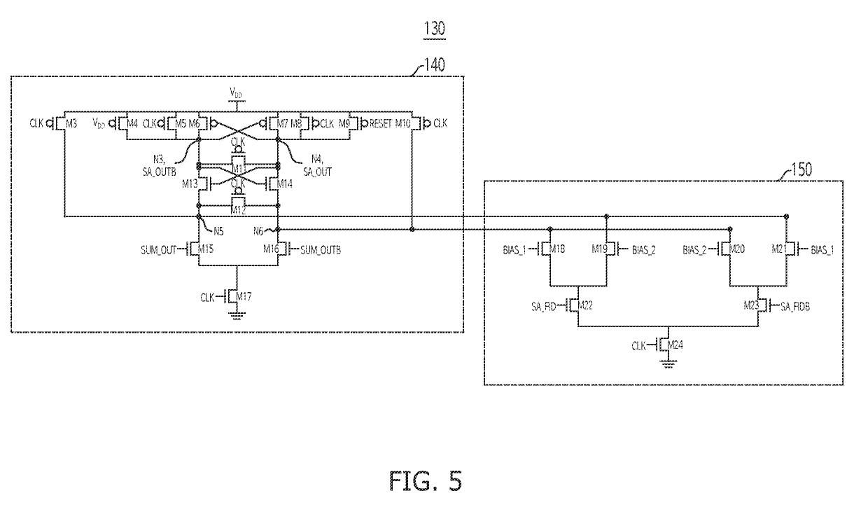

FIG. 5 is a diagram for describing a sampler according to some implementations of the present disclosure.

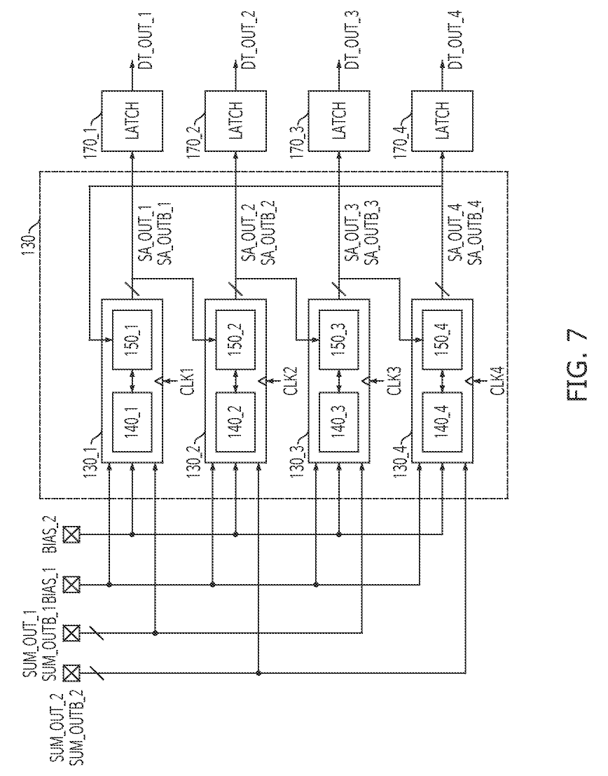

Referring to FIG. 5, the sampler 130 may include a sampling circuit 140 and a first equalization circuit 150. The sampling circuit 140 shown in FIG. 5 may be any one of the first to fourth sampling circuits described with reference to FIG. 7. Furthermore, the first equalization circuit 150 shown in FIG. 5 may be any one of the corresponding the 1_1 to 1_4 equalization circuits described with reference to FIG. 7.

The sampling circuit 140 may receive the summation output signals SUM_OUT and SUM_OUTB and may generate sampling signals SA_OUT and SA_OUTB by sampling SUM_OUT and SUM_OUTB based on a clock signal CLK. The generated sampling signals SA_OUT and SA_OUTB may be output through a third node N3 and a fourth node N4, respectively. The first equalization circuit 150 may be coupled to the sampling circuit 140 through lines connected at a fifth node N5 and a sixth node N6.

In other words, the third node N3 and the fourth node N4 may be nodes for outputting the sampling signals SA_OUT and SA_OUTB. Also, the fifth node N5 and the sixth node N6 may be nodes that couple the sampling circuit 140 to the first equalization circuit 150.

The first equalization circuit 150 may receive feedback sampling signals SA_FID and SA_FIDB, and may equalize the sampling signals SA_OUT and SA_OUTB based on the feedback sampling signals SA_FID and SA_FIDB. For example, the first equalization circuit 150 may feed back a previously sampled signal that is earlier than the currently sampled signal so as to equalize the currently sampled signal. In some implementations, the feedback sampling signals SA_FID and SA_FIDB may be signals sampled 1 UI prior to the sampling signals SA_OUT and SA_OUTB.

The sampling circuit 140 may include third to seventeenth transistors M3 through M17. The transistors M3 through M12 may be implemented as PMOS transistors, and the transistors M13 through M17 may be implemented as NMOS transistors, but the present disclosure is not limited thereto.

The third transistor M3 may receive the clock signal CLK through its gate, may receive the supply voltage VDD through its source, and may be connected to the fifth node N5 through its drain. The fifth transistor M5 may receive the clock signal CLK through its gate, may receive the supply voltage VDD through its source, and may be connected to the third node N3 through its drain. The eighth transistor M8 may receive the clock signal CLK through its gate, may receive the supply voltage VDD through its source, and may be connected to the fourth node N4 through its drain. The tenth transistor M10 may receive the clock signal CLK through its gate, may receive the supply voltage VDD through its source, and may be connected to the sixth node N6 through its drain. Each of the third transistor M3, the fifth transistor M5, the eighth transistor M8, and the tenth transistor M10 may control the amount of current flowing between its source and drain terminals based on the state (for example, high or low) of the clock signal CLK or may operate as a switch. Additionally, while the clock signal CLK remains at a low level, current may flow through each of M3, M5, M8, and M10 so that a precharge operation is performed on each node.

The fourth transistor M4 may receive the supply voltage VDD through both its gate and source, and may be connected to the third node N3 through its drain.

The sixth transistor M6 may have its gate coupled to the fourth node N4, receive the supply voltage VDD through its source, and be connected to the third node N3 through its drain. The seventh transistor M7 may have its gate coupled to the third node N3, receive the supply voltage VDD through its source, and be connected to the fourth node N4 through its drain. In other words, the sixth transistor M6 and the seventh transistor M7 may be transistors to which the sampling signals SA_OUT and SA_OUTB are input through their gates.

The eleventh transistor M11 may receive the clock signal CLK through its gate, be connected to the third node N3 through its source, and be connected to the fourth node N4 through its drain. The twelfth transistor M12 may receive the clock signal CLK through its gate, be connected to the fifth node N5 through its source, and be connected to the sixth node N6 through its drain. Each of the eleventh transistor M11 and the twelfth transistor M12 may operate to maintain the voltage levels of connected nodes in equilibrium. Specifically, the eleventh transistor M11 may adjust the voltages of the third node N3 and the fourth node N4 according to the state of the clock signal CLK, and the twelfth transistor M12 may keep the voltages of the fifth node N5 and the sixth node N6 equal.

The ninth transistor M9 may receive a reset signal RESET through its gate, may receive the supply voltage VDD through its source, and may be connected to the fourth node N4 through its drain. The ninth transistor M9 may set the initial state of the sampling circuit 140 and the first equalization circuit 150 based on the reset signal RESET. In some implementations, the ninth transistor M9 may be referred to as a reset transistor. The reset signal RESET may be activated for about 2 UI before to about 2 UI after the start of the sampling operation, during which time the sampling signal SA_OUT may be set to an initial value (for example, a logical “1”). This allows the sampling signal to maintain a stable initial state and may improve accuracy in subsequent sampling operations. However, the interval in which the reset signal RESET is activated is not limited to the description above.

In implementations of the present disclosure, a reset effect may be implemented with a simplified structure using a single PMOS transistor (for example, the ninth transistor M9) rather than implementing a separate logic circuit. In addition, the ninth transistor M9 may be designed with an appropriate size (W/L ratio) so that the node voltage can be quickly controlled to offset the effect of the first equalization circuit 150 based on the reset signal RESET. Through this, the ninth transistor M9 may hold the sampling signal SA_OUT at a first logic level (for example, a high level) based on the reset signal RESET. In some implementations, the W/L ratio (width-to-length ratio) of the channel of the ninth transistor M9 may be larger than the W/L ratios of the channels of each of the eighteenth to twenty-first transistors M18 to M21. Hence, the sampler 130 may perform a stable reset operation without complicated logic, and the simplicity and efficiency of the sampling circuit 140 may be maintained.

The thirteenth transistor M13 may have its gate coupled to the fourth node N4, its drain coupled to the third node N3, and its source coupled to the fifth node N5. The fourteenth transistor M14 may have its gate coupled to the third node N3, its drain coupled to the fourth node N4, and its source coupled to the sixth node N6.

The fifteenth transistor M15 may receive the summation output signal SUM_OUT through its gate, be connected to the fifth node N5 through its drain, and be connected through its source to the drain of a seventeenth transistor M17. The sixteenth transistor M16 may receive the summation output signal SUM_OUTB through its gate, be connected to the sixth node N6 through its drain, and be connected through its source to the drain of the seventeenth transistor M17. The seventeenth transistor M17 may receive the clock signal CLK through its gate, be connected through its drain to the source of either the fifteenth transistor M15 or the sixteenth transistor M16, and be connected to a ground terminal through its source. In other words, the fifteenth transistor M15 and the sixteenth transistor M16 may be transistors to which the summation output signals SUM_OUT and SUM_OUTB are input through their gates.

The first equalization circuit 150 may include eighteenth to twenty-fourth transistors M18 through M24. The transistors M18 through M24 may be implemented as NMOS transistors, but they are not limited thereto.

The eighteenth transistor M18 may receive a first bias voltage BIAS_1 through its gate, may be connected to the sixth node N6 through its drain, and may be connected to the drain of a twenty-second transistor M22 through its source. The nineteenth transistor M19 may receive a second bias voltage BIAS_2 through its gate, may be connected to the fifth node N5 through its drain, and may be connected to the drain of the twenty-second transistor M22 through its source. The twentieth transistor M20 may receive the second bias voltage BIAS_2 through its gate, may be connected to the sixth node N6 through its drain, and may be connected to the drain of a twenty-third transistor M23 through its source. The twenty-first transistor M21 may receive the first bias voltage BIAS_1 through its gate, may be connected to the fifth node N5 through its drain, and may be connected to the drain of the twenty-third transistor M23 through its source. Depending on the voltage difference between the first bias voltage BIAS_1 and the second bias voltage BIAS_2, the amount of current flowing into the first equalization circuit 150 through either the fifth node N5 or the sixth node N6 may be adjusted. Accordingly, the first equalization circuit 150 may perform an equalization operation to reduce inter-symbol interference of the input signal and improve signal quality.

The twenty-second transistor M22 may receive the feedback sampling signal SA_FID through its gate, be connected to the eighteenth transistor M18 or the nineteenth transistor M19 through its drain, and be connected to the drain of a twenty-fourth transistor M24 through its source. The twenty-third transistor M23 may receive the feedback sampling signal SA_FIDB through its gate, be connected to the twentieth transistor M20 or the twenty-first transistor M21 through its drain, and be connected to the drain of the twenty-fourth transistor M24 through its source. Each of the twenty-second transistor M22 and the twenty-third transistor M23 may operate as a switch that controls current flow depending on the state of the feedback sampling signals SA_FID and SA_FIDB. For example, if SA_FID is high and SA_FIDB is low, the twenty-second transistor M22 may turn on while the twenty-third transistor M23 may turn off, so that a current path is established through the twenty-second transistor M22. In other words, if the feedback sampling signal is applied to the gate of the twenty-second transistor M22, the differential feedback sampling signal may be applied to the gate of the twenty-third transistor M23.

The twenty-fourth transistor M24 may receive the clock signal CLK through its gate, be connected to the twenty-second transistor M22 or the twenty-third transistor M23 through its drain, and be connected to the ground terminal through its source.

According to various implementations of the present disclosure, between the transistors (for example, M22 and M23) to which the feedback sampling signals SA_FID and SA_FIDB, generated 1 UI before the sampling signals SA_OUT and SA_OUTB, are input and the sampling circuit 140, transistors (for example, M18, M19, M20, M21) for determining an equalization coefficient may be disposed. In addition, because the transistors that determine the equalization coefficient are disposed above the transistors to which the feedback sampling signals SA_FID and SA_FIDB are input, the current flow path of the feedback signal may be set more concisely. Such a configuration reduces signal delay in the feedback path, and feedback time may be effectively reduced.

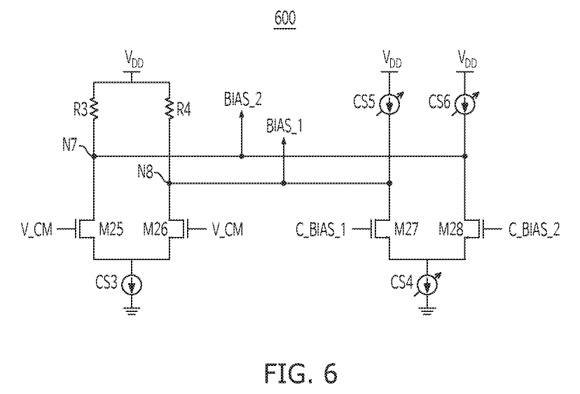

FIG. 6 is a diagram for describing a bias voltage generation circuit according to some implementations of the present disclosure.

Referring to FIG. 6, the bias voltage generation circuit 600 may include third and fourth resistors R3 and R4, transistors M25 to M28, and third to sixth current sources CS3 to CS6. The transistors M25 to M28 may be implemented as NMOS transistors, but they are not limited thereto.

The bias voltage generation circuit 600 may be configured to output a first bias voltage BIAS_1 and a second bias voltage BIAS_2 based on a first bias control signal C_BIAS_1 and a second bias control signal C_BIAS_2. Further, the bias voltage generation circuit 600 may be configured to generate the first bias voltage BIAS_1 and the second bias voltage BIAS_2 based on bias currents generated by current sources (for example, CS3 to CS6). The first bias voltage BIAS_1 and the second bias voltage BIAS_2 output by the bias voltage generation circuit 600 may be provided to the first equalization circuit 150 of FIG. 5.

One end of the third resistor R3 may be connected to the supply voltage VDD, and the other end of the third resistor R3 may be connected to a seventh node N7. One end of the fourth resistor R4 may be connected to the supply voltage VDD, and the other end of the fourth resistor R4 may be connected to an eighth node N8.

The twenty-fifth transistor M25 may receive a common voltage V_CM through its gate, be connected to the seventh node N7 through its drain, and be connected to the third current source CS3 through its source. The twenty-sixth transistor M26 may receive the common voltage V_CM through its gate, be connected to the eighth node N8 through its drain, and be connected to the third current source CS3 through its source.

The third current source CS3 may generate a bias current flowing through the twenty-fifth transistor M25. In some implementations, the third current source CS3 may be a transistor that receives a bias voltage through its gate terminal, is connected to the transistors M25 and M26 at its drain terminal, and is connected to a ground voltage at its source terminal.

The twenty-seventh transistor M27 may receive the first bias control signal C_BIAS_1 through its gate, be connected to the eighth node N8 through its drain, and be connected to the fourth current source CS4 through its source. The twenty-eighth transistor M28 may receive the second bias control signal C_BIAS_2 through its gate, be connected to the seventh node N7 through its drain, and be connected to the fourth current source CS4 through its source. In some implementations, each of the twenty-seventh transistor M27 and the twenty-eighth transistor M28 may operate as a switch that controls current flow depending on the state of the bias control signals C_BIAS_1 and C_BIAS_2. For example, if the first bias control signal C_BIAS_1 is at a high level and the second bias control signal C_BIAS_2 is at a low level, the twenty-seventh transistor M27 may turn on, and the twenty-eighth transistor M28 may turn off, thereby forming a path for current to flow through M27.

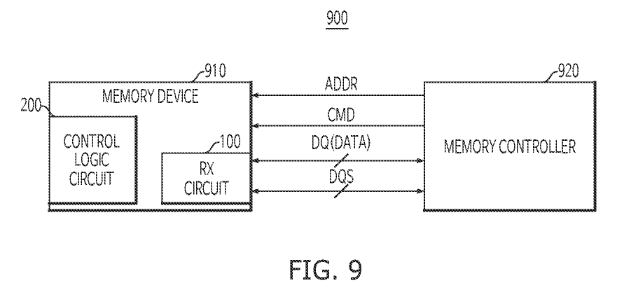

In some implementations, when the receiver circuit 100 according to the present disclosure is implemented in a memory device, a control logic circuit (see FIG. 9) may provide the first bias control signal C_BIAS_1 and the second bias control signal C_BIAS_2 to the bias voltage generation circuit 600.

In some implementations, the first bias control signal C_BIAS_1 and the second bias control signal C_BIAS_2 may be determined based on a tap polarity of the first equalization circuit 150. For example, if the first equalization circuit 150 has a first tap polarity, the first bias control signal C_BIAS_1 may be at a high level so that the twenty-seventh transistor M27 is activated (or strongly inverted), and the second bias control signal C_BIAS_2 may be at a low level so that the twenty-eighth transistor M28 is deactivated (or weakly or moderately inverted). In this case, the first bias voltage BIAS_1 may be smaller than the second bias voltage BIAS_2. Conversely, if the first equalization circuit 150 has a second tap polarity, the first bias control signal C_BIAS_1 may be at a low level so that the twenty-seventh transistor M27 is deactivated (or weakly or moderately inverted), and the second bias control signal C_BIAS_2 may be at a high level so that the twenty-eighth transistor M28 is activated (or strongly inverted). In that case, the first bias voltage BIAS_1 may be greater than the second bias voltage BIAS_2. Through such a configuration, the first bias voltage BIAS_1 and the second bias voltage BIAS_2 output from the bias voltage generation circuit 600 may be controlled. The tap polarity associated with the first equalization circuit 150 may be determined by the control logic circuit.

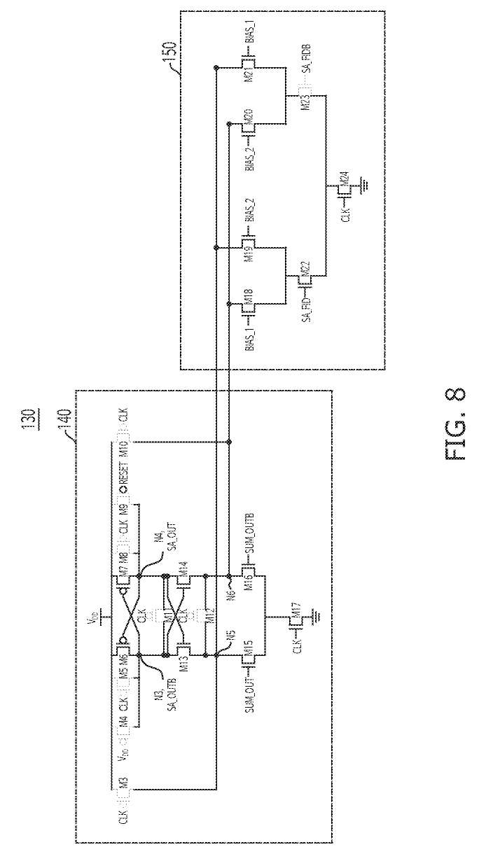

The fourth current source CS4 may generate a bias current flowing through either the twenty-seventh transistor M27 or the twenty-eighth transistor M28. In some implementations, the fourth current source CS4 may be a transistor that receives a bias voltage through its gate terminal, is connected to the transistors M27 and M28 at its drain terminal, and is connected to a ground voltage at its source terminal. Depending on the size of the bias current generated by the fourth current source CS4, the difference between the first bias voltage BIAS_1 and the second bias voltage BIAS_2 output from the bias voltage generation circuit 600 may be adjusted. Consequently, the equalization coefficient applied to the first equalization circuit 150 of FIG. 5 may be adjusted. The magnitude of the bias current generated by the fourth current source CS4 may be controlled by the control logic circuit. A more detailed description of the equalization coefficient is provided below with reference to FIG. 8.

The fifth current source CS5 may generate a bias current flowing through a line connected to the eighth node N8. The sixth current source CS6 may generate a bias current flowing through a line connected to the seventh node N7. In some implementations, the magnitudes of the bias currents generated by each of the fifth current source CS5 and the sixth current source CS6 may be the same, but they are not limited thereto.

According to various implementations of the present disclosure, based on the bias current generated by the fourth current source CS4, the difference between the first bias voltage BIAS_1 and the second bias voltage BIAS_2 output from the bias voltage generation circuit 600 may be adjusted. That is, the equalization coefficient may be determined based on the bias current generated by the fourth current source CS4. Through such a configuration, the equalization coefficient applied to the first equalization circuit 150 may be stably maintained without being affected by variations in the supply voltage VDD.

FIG. 7 is a diagram for describing a sampler according to some implementations of the present disclosure.

Referring to FIG. 7, the sampler 130 may include a first sampler 130_1 that includes a first sampling circuit 140_1 and a 1_1 equalization circuit 150_1, a second sampler 130_2 that includes a second sampling circuit 140_2 and a 1_2 equalization circuit 150_2, a third sampler 130_3 that includes a third sampling circuit 140_3 and a 1_3 equalization circuit 150_3, and a fourth sampler 130_4 that includes a fourth sampling circuit 140_4 and a 1_4 equalization circuit 150_4.

The first sampler 130_1 may sample first summation output signals SUM_OUT_1 and SUM_OUTB_1 according to a first clock signal CLK1 to generate first sampling signals SA_OUT_1 and SA_OUTB_1. Specifically, the first sampling circuit 140_1 may sample the first summation output signals SUM_OUT_1 and SUM_OUTB_1 in synchronization with the first clock signal CLK1. Also, the 1_1 equalization circuit 150_1 may equalize the first sampling signals SA_OUT_1 and SA_OUTB_1 in synchronization with the first clock signal CLK1. The 1_1 equalization circuit 150_1 may apply an equalization coefficient obtained based on the voltage difference between the first bias voltage BIAS_1 and the second bias voltage BIAS_2, so as to equalize the first sampling signals SA_OUT_1 and SA_OUTB_1. The first sampling signals SA_OUT_1 and SA_OUTB_1 sampled at the first sampler 130_1 may be provided as feedback to the 1_2 equalization circuit 150_2.

The second sampler 130_2 may sample second summation output signals SUM_OUT_2 and SUM_OUTB_2 according to a second clock signal CLK2 to generate second sampling signals SA_OUT_2 and SA_OUTB_2. Specifically, the second sampling circuit 140_2 may sample the second summation output signals SUM_OUT_2 and SUM_OUTB_2 in synchronization with the second clock signal CLK2. Also, the 1_2 equalization circuit 150_2 may equalize the second sampling signals SA_OUT_2 and SA_OUTB_2 in synchronization with the second clock signal CLK2. The 1_2 equalization circuit 150_2 may apply an equalization coefficient obtained based on the voltage difference between the first bias voltage BIAS_1 and the second bias voltage BIAS_2, so as to equalize the second sampling signals SA_OUT_2 and SA_OUTB_2. The second sampling signals SA_OUT_2 and SA_OUTB_2 sampled at the second sampler 130_2 may be provided as feedback to the 1_3 equalization circuit 150_3.

The third sampler 130_3 may sample the first summation output signals SUM_OUT_1 and SUM_OUTB_1 according to a third clock signal CLK3 to generate third sampling signals SA_OUT_3 and SA_OUTB_3. Specifically, the third sampling circuit 140_3 may sample the first summation output signals SUM_OUT_1 and SUM_OUTB_1 in synchronization with the third clock signal CLK3. Also, 1_3 equalization circuit 150_3 may equalize the third sampling signals SA_OUT_3 and SA_OUTB_3 in synchronization with the third clock signal CLK3. The 1_3 equalization circuit 150_3 may apply an equalization coefficient obtained based on the voltage difference between the first bias voltage BIAS_1 and the second bias voltage BIAS_2, so as to equalize the third sampling signals SA_OUT_3 and SA_OUTB_3. The third sampling signals SA_OUT_3 and SA_OUTB_3 sampled at the third sampler 130_3 may be provided as feedback to the 1_4 equalization circuit 150_4.

The fourth sampler 130_4 may sample the second summation output signals SUM_OUT_2 and SUM_OUTB_2 according to a fourth clock signal CLK4 to generate fourth sampling signals SA_OUT_4 and SA_OUTB_4. Specifically, the fourth sampling circuit 140_4 may sample the second summation output signals SUM_OUT_2 and SUM_OUTB_2 in synchronization with the fourth clock signal CLK4. Also, the 1_4 equalization circuit 150_4 may equalize the fourth sampling signals SA_OUT_4 and SA_OUTB_4 in synchronization with the fourth clock signal CLK4. The 1_4 equalization circuit 150_4 may apply an equalization coefficient obtained based on the voltage difference between the first bias voltage BIAS_1 and the second bias voltage BIAS_2, so as to equalize the fourth sampling signals SA_OUT_4 and SA_OUTB_4. The fourth sampling signals SA_OUT_4 and SA_OUTB_4 sampled at the fourth sampler 130_4 may be provided as feedback to the 1_1 equalization circuit 150_1.

The first clock signal CLK1, the second clock signal CLK2, the third clock signal CLK3, and the fourth clock signal CLK4 are clock signals having a 90-degree phase difference, so they may have the same frequency but cause signals to occur at different time points. For example, if the first clock signal CLK1 is a reference clock signal, the second clock signal CLK2 may have a phase delayed by 90 degrees relative to the first clock signal CLK1. Also, the third clock signal CLK3 may have a 180-degree phase difference relative to the first clock signal CLK1 and a 90-degree phase difference relative to the second clock signal CLK2, and the fourth clock signal CLK4 may have a 180-degree phase difference relative to the second clock signal CLK2 and a 90-degree phase difference relative to the third clock signal CLK3.

In some implementations, where the receiver circuit according to the present disclosure is implemented in a memory device, the first to fourth clock signals CLK1 to CLK4 may be generated based on a data strobe signal DQS received from a memory controller.

In some implementations, the receiver circuit (for example, 100 in FIG. 3) according to the present disclosure may further include first to fourth latch circuits 170_1 to 170_4. Each of the first to fourth latch circuits 170_1 to 170_4 may receive the first to fourth sampling signals SA_OUT_1 to SA_OUT_4, SA_OUTB_1 to SA_OUTB_4, respectively, and may generate and output first to fourth output data DT_OUT_1 to DT_OUT_4, respectively.

FIG. 8 is a diagram for describing the operation of the sampler according to some implementations of the present disclosure.

Referring to FIG. 8, an operational state of the sampler in some implementations of the present disclosure is illustrated. Transistors illustrated with gray shading (for example, the third transistor M3, the fourth transistor M4, etc.) may be transistors that are off at the moment a signal is sampled.

In some implementations, when the clock signal CLK is low, the third transistor M3, the fifth transistor M5, the eighth transistor M8, the tenth transistor M10, the eleventh transistor M11, and the twelfth transistor M12 may turn on, causing main nodes (for example, the third node N3, the fourth node N4, the fifth node N5, and the sixth node N6) of the sampling circuit 140 to reach a precharge state. In the precharge state, the voltage levels of each node may be kept at equal levels.

Afterward, when the clock signal CLK switches to high, the seventeenth transistor M17 may turn on. Also, the fifteenth transistor M15 and the sixteenth transistor M16 may turn on according to the summation output signals SUM_OUT and SUM_OUTB. During this process, current flows through the fifteenth transistor M15 and the sixteenth transistor M16, and the voltage levels of the fifth node N5 and the sixth node N6 may gradually decrease. As the voltage levels of N5 and N6 decrease in this manner, the thirteenth transistor M13 and the fourteenth transistor M14 may turn on, allowing current to flow through M13 and M14.

Further, the current flowing through the thirteenth transistor M13 and the fourteenth transistor M14 may reduce the voltage at the third node N3 or the fourth node N4, thereby causing either the sixth transistor M6 or the seventh transistor M7 to switch on. After one of the sixth transistor M6 or the seventh transistor M7 switches on, the supply voltage VDD may flow through whichever of the transistor M6 or M7 is on to the third node N3 or the fourth node N4, so that the corresponding node voltage stays at a high level.

Meanwhile, whichever of the sixth transistor M6 or the seventh transistor M7 does not switch to a high level will continue to receive the high-level voltage from the third node N3 or the fourth node N4, and thus may remain off. As a result, the node among the third node N3 and the fourth node N4 that does not switch to the high level will continuously decrease in voltage and remain at a low level, eventually generating a low-level sampling signal at that node. Through this operation, the sampling circuit 140 may generate the differential sampling signals SA_OUT and SA_OUTB.

In some implementations, the sampler 130 may operate based on feedback data, including the first equalization circuit 150. With the first equalization circuit 150 included, an equalization operation may be performed based on the feedback sampling signals SA_FID and SA_FIDB generated 1 UI earlier than the sampling signals SA_OUT and SA_OUTB.

Specifically, each of the feedback sampling signals SA_FID and SA_FIDB is input to the gates of the twenty-second transistor M22 and the twenty-third transistor M23, respectively, so that one of M22 or M23 switches on. Through this operation, a current flow path is set based on the feedback signal, and the amount of current flowing from either the fifth node N5 or the sixth node N6 to the ground terminal is adjusted. In other words, depending on the feedback sampling signals SA_FID and SA_FIDB, either a feedback path including the eighteenth transistor M18 and the nineteenth transistor M19 or a feedback path including the twentieth transistor M20 and the twenty-first transistor M21 may be chosen.

Additionally, as described with reference to FIG. 6, based on the difference between the bias voltages BIAS_1 and BIAS_2 that are input to the transistors M18 to M21, the amount of current flowing from the fifth node N5 and the sixth node N6 to the ground terminal may be regulated. Thus, the sampling threshold at which the sampling signals SA_OUT and SA_OUTB are determined to be at a specific voltage level may be shifted to a higher voltage level. Through such a configuration, the first equalization circuit 150 may perform an equalization operation, enhancing the accuracy and reliability of the sampling operation.

For example, if the feedback sampling signal SA_FID is at a high level and the first equalization circuit 150 has a first tap polarity, because the second bias voltage BIAS_2 is higher than the first bias voltage BIAS_1, the current flowing through the nineteenth transistor M19 may be greater than the current flowing through the eighteenth transistor M18. Further, if the feedback sampling signal SA_FID is at a high level and the first equalization circuit 150 has a second tap polarity, because the first bias voltage BIAS_1 is higher than the second bias voltage BIAS_2, the current flowing through the eighteenth transistor M18 may be greater than the current flowing through the nineteenth transistor M19. As another example, if the feedback sampling signal SA_FID is at a low level and the first equalization circuit 150 has the first tap polarity, because the second bias voltage BIAS_2 is higher than the first bias voltage BIAS_1, the current flowing through the twentieth transistor M20 may be greater than the current flowing through the twenty-first transistor M21. Moreover, if the feedback sampling signal SA_FID is at a high level and the first equalization circuit 150 has the second tap polarity, because the first bias voltage BIAS_1 is higher than the second bias voltage BIAS_2, the current flowing through the twenty-first transistor M21 may be greater than the current flowing through the twentieth transistor M20.

Through such a configuration, the threshold for determining the sampling signals SA_OUT and SA_OUTB output to the third node N3 or the fourth node N4 may be more finely controlled. For example, if the summation output signal SUM_OUT is input at a high level through the fifteenth transistor M15, the voltage level of the third node N3 may decrease, which may switch the drain voltage of the seventh transistor M7 to a high level. During this process, the first equalization circuit 150 may control the voltage levels of the fifth node N5 and the sixth node N6 so as to cause the voltage level of the sixth node N6 to decrease more than that of the fifth node N5. Such an operation may more precisely control the standard at which the seventh transistor M7 switches to a high level, thereby improving the accuracy of the sampling signals SA_OUT and SA_OUTB.

As described, the difference between the first bias voltage BIAS_1 and the second bias voltage BIAS_2 determines the ratio of current branching into the first equalization circuit 150 through the fifth node N5 and the sixth node N6, and this difference may be referred to as an “equalization coefficient.” The equalization coefficient is a measure of how strongly the first equalization circuit 150 adjusts voltage levels and may be an important parameter used to optimize signal correction in the feedback path.

For example, when the equalization coefficient is high, the current difference branching into the first equalization circuit 150 through the fifth node N5 or the sixth node N6 may increase, so a greater change in voltage level may occur in that path. Conversely, when the equalization coefficient is low, the difference in branching current may decrease, and the amplitude of the voltage change may be reduced.

Such an equalization coefficient may be adjusted based on the settings of the bias voltage generation circuit, the polarity of the feedback signal, or the tap polarity of the first equalization circuit 150, thereby further improving the accuracy of the sampling signals SA_OUT and SA_OUTB and the quality of data signals.

The foregoing examples are merely illustrative implementations, and the accuracy of the sampling signals SA_OUT and SA_OUTB may be enhanced by various operational examples.

FIG. 9 is a block diagram for describing a memory system according to some implementations of the present disclosure. Referring to FIG. 9, the memory system 900 may include a memory device 910 and a memory controller 920.

The memory controller 920 may write data DATA into the memory device 910 or perform an operation of reading out data DATA stored in the memory device 910. For example, the memory controller 920 may generate a command CMD and an address ADDR for writing data DATA into the memory device 910 or for reading data DATA stored in the memory device 910. In some implementations, the memory controller 920 may be at least one of a memory controller, a system-on-chip (SoC) such as an application processor (AP), a central processing unit (CPU), a digital signal processor (DSP), or a graphics processing unit (GPU) controlling the memory device 910.

The memory device 910 may store data DATA received through a plurality of data lines DQ under the control of the memory controller 920, or may transfer data DATA stored in the memory device 910 to the memory controller 920 through the plurality of data lines DQ. The memory device 910 may transfer data to the memory controller 920 in synchronization with a data strobe signal provided through a data strobe line DQS. For example, data DATA may be transmitted and received between the memory device 910 and the memory controller 920 through multiple data lines DQ and a data strobe line DQS.

In some implementations, the memory device 910 may include a dynamic random access memory (DRAM). However, the scope of the present disclosure is not limited thereto, and the memory device 910 may include at least one among various memory devices such as an SRAM (Static RAM), an SDRAM (Synchronous DRAM), a ROM (Read Only Memory), a PROM (Programmable ROM), an EPROM (Electrically Programmable ROM), an EEPROM (Electrically Erasable and Programmable ROM), a flash memory device, a PRAM (Phase-change RAM), an MRAM (Magnetic RAM), an RRAM (Resistive RAM), or an FRAM (Ferroelectric RAM).

By way of example, the memory device 910 and the memory controller 920 may communicate based on a Double Data Rate (DDR) interface, but the scope of the present disclosure is not limited thereto. For example, the memory device 910 and the memory controller 920 may communicate based on at least one among various interfaces such as USB (Universal Serial Bus), MMC (Multimedia Card), PCI (Peripheral Component Interconnection), PCI-E (PCI-express), ATA (Advanced Technology Attachment), SATA (Serial-ATA), PATA (Parallel-ATA), SCSI (Small Computer Small Interface), ESDI (Enhanced Small Disk Interface), IDE (Integrated Drive Electronics), MIPI (Mobile Industry Processor Interface), NVM-e (Nonvolatile Memory-express), or a NAND interface.

In some implementations, the memory device 910 may include a receiver circuit 100 and a control logic circuit 200. The receiver circuit 100 may be configured to adjust the pulse width corresponding to a current data bit based on data received from the memory controller 920. For example, the receiver circuit 100 may remove noise of the current data based on previously received data. The control logic circuit 200 may overall control the receiver circuit 100, thereby controlling equalization operations of the receiver circuit 100. For example, the control logic circuit 200 may adjust a bias voltage level in the receiver circuit 100 or adjust a tap polarity of the first equalization circuit. The receiver circuit 100 and the control logic circuit 200 according to the present disclosure are described in more detail with reference to FIGS. 1-8.

As described above, in the receiver circuit 100, the first equalization circuit may be integrated into the sampler, so that the output signal of the sampler generated in the previous phase domain may be directly provided to the first equalization circuit of the next phase domain. Thus, the feedback path is shortened, and the feedback time may be kept within 1 UI. Through such a configuration, the receiver circuit 100 may more rapidly remove noise and inter-symbol interference that may arise in the current data signal based on the current clock signal. Accordingly, the receiver circuit 100 may stably and reliably process data even in a high-speed data transmission environment, which contributes to improving data transmission reliability between the memory device 910 and the memory controller 920 supporting high-speed interfaces.

Implementations of the present disclosure have been described with reference to a receiver circuit 100 applied to the memory device 910 (i.e., an example of FIG. 9). By way of example, the configurations of the memory device 910 and the memory controller 920 set forth above are intended merely to describe exemplary implementations of the present disclosure, and the scope of the present disclosure is not limited thereto. For example, the receiver circuit 100 according to the present disclosure may be applied to signal transmitters, signal receivers, or various electronic devices configured to transmit and receive various information through signal lines. Also, the receiver circuit 100 according to the present disclosure may be applied not only to data lines or data signals but also to receiving or transmitting various signals.

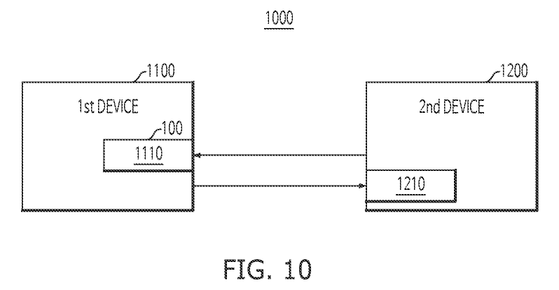

FIG. 10 is a block diagram illustrating an example of an electronic device having a receiver circuit according to some implementations of the present disclosure.

Referring to FIG. 10, a system 1000 may include a first device 1100 and a second device 1200. Each of the first device 1100 and the second device 1200 may be an apparatus that transmits and receives information signals such as data signals, electrical signals, analog signals, or digital signals within the system 1000. By way of example, each of the first device 1100 and the second device 1200 may be an information processing device such as a signal transmitter, a signal receiver, an IP (intellectual property) block, an electronic module, or an electronic circuit.

Each of the first device 1100 and the second device 1200 may include receiver circuits 1110 and 1210, respectively. Each of the receiver circuits 1110 and 1210 may be a receiver circuit described with reference to FIGS. 1-8. In other words, each of the receiver circuits 1110 and 1210 may be configured to filter noise from a signal received by the first device 1100 or the second device 1200.

The preferred implementations of the present disclosure set forth above are disclosed merely by way of example, and those of ordinary skill in the art will recognize that various modifications, changes, and additions are possible without departing from the spirit and scope of the present disclosure, and such modifications, changes, and additions should be construed as falling within the scope of the appended claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Those of ordinary skill in the art will appreciate that various substitutions, modifications, and changes may be made without departing from the technical spirit of the present disclosure, and therefore the present disclosure is not limited by the above-described implementations or the accompanying drawings.

What is claimed is:

1. A memory device comprising:
a buffer configured to compare a data signal to a reference voltage and generate an amplified signal;
a summation circuit configured to generate a summation output signal based on the amplified signal; and
a sampler comprising (i) a sampling circuit configured to generate a sampling signal by sampling the summation output signal based on a clock signal, and (ii) a first equalization circuit coupled to the sampling circuit and configured to equalize the sampling signal based on a feedback sampling signal sampled prior to the sampling signal,
wherein the first equalization circuit comprises (i) a first transistor circuit configured to receive the feedback sampling signal, and (ii) a second transistor circuit between the first transistor circuit and the sampling circuit, wherein the second transistor circuit is configured to receive a bias voltage associated with an equalization coefficient.

2. The memory device according to claim 1, wherein the sampling signal comprises a first sampling signal and a second sampling signal, and
wherein the sampling circuit comprises
a first node configured to output the first sampling signal and a second node configured to output the second sampling signal, and
a third node and a fourth node that are connected to the first equalization circuit.

3. The memory device according to claim 2, wherein the sampling circuit comprises:
a third transistor circuit connected between a supply voltage and at least one of the first node or the second node, and having a gate configured to receive the sampling signal; and
a fourth transistor circuit connected to at least one of the third node or the fourth node, and having a gate configured to receive the summation output signal.

4. The memory device according to claim 3, wherein the first transistor circuit comprises:
a 1_1 transistor having a gate configured to receive the feedback sampling signal, and
a 1_2 transistor having a gate configured to receive a differential signal of the feedback sampling signal.

5. The memory device according to claim 4, wherein the second transistor circuit comprises:
a 2_1 transistor connected to the third node and the 1_1 transistor;
a 2_2 transistor connected to the fourth node and the 1_1 transistor;
a 2_3 transistor connected to the third node and the 1_2 transistor; and
a 2_4 transistor connected to the fourth node and the 1_2 transistor.

6. The memory device according to claim 5, wherein each of the 2_1 transistor and the 2_4 transistor comprises a respective gate configured to receive a first bias voltage, and
wherein each of the 2_2 transistor and the 2_3 transistor comprises a respective gate configured to receive a second bias voltage.

7. The memory device according to claim 6, wherein
the first equalization circuit is configured to, based on (i) the feedback sampling signal being at a first logic level and (ii) the first equalization circuit comprising a first tap polarity, regulate current flowing through the 2_2 transistor to be greater than current flowing through the 2_1 transistor,
the first equalization circuit is configured to, based on (i) the feedback sampling signal being at the first logic level and (ii) the first equalization circuit comprising a second tap polarity that is different from the first tap polarity, regulate current flowing through the 2_1 transistor to be greater than the current flowing through the 2_2 transistor,
the first equalization circuit is configured to, based on (i) the feedback sampling signal being at a second logic level and (ii) the first equalization circuit comprising the first tap polarity, regulate current flowing through the 2_3 transistor to be greater than current flowing through the 2_4 transistor, and
the first equalization circuit is configured to, based on (i) the feedback sampling signal being at the second logic level and (ii) the first equalization circuit comprising the second tap polarity, regulate current flowing through the 2_4 transistor to be greater than the current flowing through the 2_3 transistor.

8. The memory device according to claim 6, comprising a bias voltage generation circuit connected to the second transistor circuit,
wherein the bias voltage generation circuit is configured to generate, based on a bias current generated by a current source, the first bias voltage and the second bias voltage.

9. The memory device according to claim 8, wherein the equalization coefficient is determined based on the bias current.

10. The memory device according to claim 3, wherein the first equalization circuit comprises a fifth transistor circuit connected between the first transistor circuit and ground, the first equalization circuit comprises a gate configured to receive the clock signal, and
the sampling circuit comprises a sixth transistor circuit connected between the fourth transistor circuit and ground, and having a gate configured to receive the clock signal.

11. The memory device according to claim 3, wherein the sampling circuit comprises a reset transistor connected between a supply voltage and at least one of the first node or the second node, the reset transistor comprising a gate configured to receive a reset signal, and
wherein the reset transistor is configured to maintain the sampling signal at a first logic level based on the reset signal.

12. The memory device according to claim 11, wherein a width-to-length ratio (W/L) of a channel of the reset transistor is greater than a width-to-length ratio (W/L) of a channel of the second transistor circuit.

13. The memory device according to claim 1, comprising a second equalization circuit connected to the summation circuit,
wherein the second equalization circuit is configured to receive a signal sampled earlier in time than an input of the feedback sampling signal to the first equalization circuit.

14. The memory device according to claim 1, wherein the clock signal comprises first clock signal, second clock signal, third clock signal, and a fourth clock signal, each signal having a 90-degree phase difference, and
wherein the sampling circuit comprises
a first sampling circuit configured to sample the summation output signal based on the first clock signal and to generate a first sampling signal;
a second sampling circuit configured to sample the summation output signal based on the second clock signal and to generate a second sampling signal;
a third sampling circuit configured to sample the summation output signal based on the third clock signal and to generate a third sampling signal; and
a fourth sampling circuit configured to sample the summation output signal based on the fourth clock signal and to generate a fourth sampling signal.

15. The memory device according to claim 14, wherein the first equalization circuit comprises:
a 1_1 equalization circuit connected to the first sampling circuit and configured to equalize the first sampling signal;
a 1_2 equalization circuit connected to the second sampling circuit and configured to equalize the second sampling signal based on the first sampling signal;
a 1_3 equalization circuit connected to the third sampling circuit and configured to equalize the third sampling signal based on the second sampling signal; and
a 1_4 equalization circuit connected to the fourth sampling circuit and configured to equalize the fourth sampling signal based on the third sampling signal.

16. The memory device according to claim 15, wherein a node through which the first sampling signal is output is connected to the 1_2 equalization circuit,
wherein a first node configured to output the second sampling signal is connected to the 1_3 equalization circuit,
wherein a second node configured to output the third sampling signal is connected to the 1_4 equalization circuit, and
wherein a third node configured to output the fourth sampling signal is connected to the 1_1 equalization circuit.

17. The memory device according to claim 14, wherein the summation circuit comprises (i) a first summation circuit configured to generate a first summation circuit output signal based on the amplified signal and (ii) a second summation circuit configured to generate a second summation circuit output signal based on the amplified signal,
wherein a first node configured to output the first summation circuit output signal is connected to the first sampling circuit and the third sampling circuit, and
wherein a second node configured to output the second summation circuit output signal is connected to the second sampling circuit and the fourth sampling circuit.

18. A memory device comprising:
a receiver circuit configured to process a data signal received from a memory controller and generate output data; and
a control logic circuit configured to control the receiver circuit,
wherein the receiver circuit comprises
a buffer configured to compare the data signal to a reference voltage and generate an amplified signal,
a summation circuit configured to generate a summation output signal based on the amplified signal, and
a sampler comprising (i) a sampling circuit configured to generate a sampling signal by sampling the summation output signal based on a clock signal and (ii) an equalization circuit coupled to the sampling circuit and configured to equalize the sampling signal based on a feedback sampling signal sampled prior to the sampling signal, and
wherein the equalization circuit comprises (i) a first transistor circuit configured to receive the feedback sampling signal and (ii) a second transistor circuit between the first transistor circuit and the sampling circuit, wherein the second transistor circuit is configured to receive a bias voltage associated with an equalization coefficient.

19. The memory device according to claim 18, comprising a bias voltage generation circuit connected to the second transistor circuit,
wherein the bias voltage generation circuit is configured to generate, based on a bias current generated by a current source, the bias voltage that is input to a gate of the second transistor circuit, and
wherein the control logic circuit is configured to determine the bias current associated with the equalization coefficient.

20. A memory system comprising:
a memory device; and
a memory controller configured to write data into the memory device or read out data stored in the memory device,
wherein the memory device comprises
a receiver circuit configured to process a data signal received from the memory controller and generate output data, and
a control logic circuit configured to control the receiver circuit,
wherein the receiver circuit comprises
a buffer configured to compare the data signal to a reference voltage and generate an amplified signal,
a summation circuit configured to generate a summation output signal based on the amplified signal, and
a sampler comprising (i) a sampling circuit configured to generate a sampling signal by sampling the summation output signal based on a clock signal and (ii) an equalization circuit coupled to the sampling circuit and configured to equalize the sampling signal based on a feedback sampling signal sampled prior to the sampling signal, and
wherein the equalization circuit comprises (i) a first transistor circuit configured to receive the feedback sampling signal and (ii) a second transistor circuit between the first transistor circuit and the sampling circuit, wherein the second transistor circuit is configured to receive a bias voltage associated with an equalization coefficient.
